(19) United States
(12) Patent Application Publication
(10) Pub. No.: US 2026/0303990 A1
(43) Pub. Date: Oct. 1, 2026

(54) IMAGE SENSING DEVICE AND IMAGING DEVICE INCLUDING THE SAME

(71) Applicant: SK hynix Inc., Icheon-si (KR)

(72) Inventor: Sung Ho CHOI, Icheon-si (KR)

(21) Appl. No.: 19/317,548

(22) Filed: Sep. 3, 2025

(30) Foreign Application Priority Data
Mar. 25, 2025 (KR) 10-2025-0037870

(51) Int. Cl. H04N 25/59; H04N 25/78

(52) U.S. Cl. CPC H04N 25/59; H04N 25/78

(57) ABSTRACT

Image sensing devices and imaging devices are disclosed. In an embodiment, an image sensing device comprises: first and second pixels configured to convert light into electrical signal; a connection node shared by the first and second pixels and configured to receive the electrical signals; and a line capacitor configured to store a voltage of the connection node, wherein the first pixel includes: at least one first photodetector; a first floating diffusion region configured to receive photocharge from the at least one first photodetector; and a first dual conversion gain (DCG) transistor coupled between the first floating diffusion region and the connection node, and the second pixel includes: at least one second photodetector; a second floating diffusion region configured to receive photocharge from the at least one first photodetector through the line capacitor; and a second DCG transistor coupled between the connection node and the second floating diffusion region.

### PRIORITY CLAIM AND CROSS REFERENCE TO RELATED APPLICATION

This patent document claims the priority and benefits of Korean Patent Application No. 10-2025-0037870, filed Mar. 25, 2025, the entire contents of which are incorporated herein by reference for all purposes.

### TECHNICAL FIELD

The disclosed technology relates to an image sensing device and an imaging device including the same.

### BACKGROUND

With the development of the information and communication industry and the digitalization of electronic devices, high-performance image sensors are now used in a wide range of applications, including digital cameras, camcorders, mobile phones, personal communication systems (PCSs), game devices, security cameras, and medical micro cameras. Generally, an image sensor includes a pixel region and a circuit region. Each pixel may include a photodetector, such as a photodiode, and a transfer transistor. The transfer transistor is arranged between the photodiode and a floating diffusion region to transfer charges generated by the photodiode to the floating diffusion region.

### SUMMARY

The disclosed technology can be implemented in some embodiments to provide an image sensing device capable of providing sufficient electrostatic capacitance even when a plurality of photodetectors is saturated, and an imaging device including the same.

An image sensing device based on an embodiment comprises: first and second pixels adjacent to each other and configured to convert light into electrical signals, a connection node shared by the first and second pixels and configured to receive the electrical signals from the first and second pixels, and a line capacitor configured to store a voltage of the connection node, wherein the first pixel includes at least one first photodetector, a first floating diffusion region configured to receive photocharge from the at least one first photodetector, and a first dual conversion gain (DCG) transistor coupled between the first floating diffusion region and the connection node, and the second pixel includes at least one second photodetector, a second floating diffusion region configured to receive photocharge from the at least one first photodetector through the line capacitor, and a second DCG transistor coupled between the connection node and the second floating diffusion region.

An image sensing device based on an embodiment comprises: a first pixel configured to convert light into electrical signals and arranged in a first row; and a second pixel configured to convert light into electrical signals and arranged in a second row adjacent to the first row, a connection node configured to electrically connect the first and second pixels to each other, wherein the first pixel includes: at least one first photodetector; a first floating diffusion region configured to receive photocharge from the at least one first photodetector; and a first dual conversion gain (DCG) transistor coupled between the first floating diffusion region and the connection node and configured to turn on in a first mode and turn off in a second mode, and the second pixel includes: at least one second photodetector; a second floating diffusion region configured to receive photocharge from the at least one first photodetector or the at least one second photodetector; and a second DCG transistor coupled between the connection node and the second floating diffusion region and configured to turn on in both the first mode and the second mode.

An imaging device based on an embodiment comprises: an image sensing device configured to generate image data by converting an optical signal into an electrical signal; and an image signal processor configured to perform image signal processing on the image data, wherein the image sensing device includes: a first pixel; a second pixel adjacent to the first pixel, and a connection node, wherein the first and second pixels share the connection node; and a line capacitor configured to store a voltage of the connection node, wherein the first pixel includes: at least one first photodetector; a first floating diffusion region configured to receive photocharge from the at least one first photodetector; and a first dual conversion gain (DCG) transistor coupled between the first floating diffusion region and the connection node, and the second pixel includes: at least one second photodetector; a second floating diffusion region configured to receive photocharge from the at least one first photodetector through the line capacitor; and a second DCG transistor coupled between the connection node and the second floating diffusion region.

Specific details of other embodiments are included in the detailed description and drawings.

### BRIEF DESCRIPTION OF THE DRAWINGS

FIG. 1 is a block diagram showing an example of an imaging system based on an embodiment.

FIG. 2 is a block diagram showing an example of an image sensing device of an imaging system based on an embodiment.

FIG. 3 is a view showing an example of the connection relationship in an image sensing device of an imaging system based on an embodiment.

FIG. 4 is a plan view showing an example of a pixel array in an imaging system based on an embodiment.

FIG. 5 is a circuit diagram showing an example of pixels of an imaging system based on an embodiment.

FIG. 6 is a waveform diagram showing an example of signals during a light detection process of a first pixel among the pixels of FIG. 5.

FIG. 7 is a view showing an example of voltages of first and second pixels in a high conversion gain (HCG) mode of an imaging system based on an embodiment.

FIG. 8 is a view showing an example of voltages of first and second floating diffusion regions and a line capacitor in the HCG mode of an imaging system based on an embodiment.

FIG. 9 is a view showing another example of voltages of the first and second floating diffusion regions and the line capacitor in the HCG mode of an imaging system based on an embodiment.

FIG. 10 is a view showing an example of voltages of the first and second floating diffusion regions and the line capacitor in a low conversion gain (LCG) mode of an imaging system based on an embodiment.

FIG. 11 is a waveform diagram showing an example of the output voltage of a first pixel in an imaging system based on an embodiment.

FIG. 12 is a waveform diagram showing an example of reset periods of photodetectors of a first pixel in an imaging system based on an embodiment.

FIG. 13 is a waveform diagram showing an example of signals during a light detection process of a second pixel among the pixels shown in FIG. 5.

### DETAILED DESCRIPTION

Like reference numerals refer to like elements. In addition, the drawings may exaggerate thicknesses, proportions, and dimensions of components to facilitate a clear understanding of the technical content. The term “and/or” includes any combinations of one or more of the associated configurations.

Terms such as “first” and “second,” may be used to describe various components, and such terms are merely used for convenience to distinguish one component from another. For example, a first component may be referred to as a second component, and similarly, a second component may also be referred to as a first component.

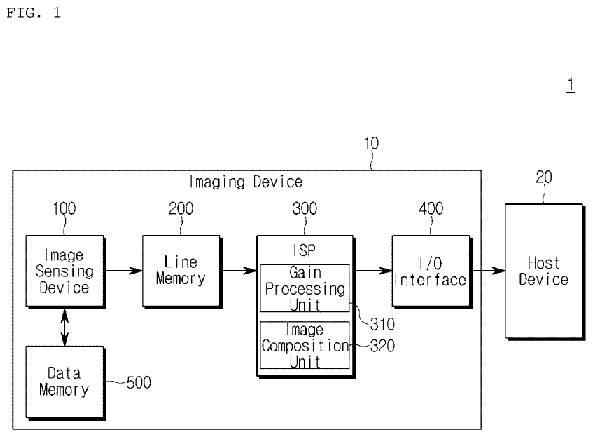

FIG. 1 is a block diagram showing an imaging system based on an embodiment.

Referring to FIG. 1, an imaging system 1 may mean a device that detects motions, as well as a device such as a digital still camera for capturing still images or a digital video camera for capturing videos. For example, the imaging device 10 may be implemented as a digital single lens reflex (DSLR) camera, a mirrorless camera, or a smartphone, but it is not limited thereto. The imaging device 10 may be a concept including a device capable of capturing subjects and generating images by including a lens and an image capturing device.

The imaging system 1 may include an imaging device 10 and a host device 20.

The imaging device 10 may include an image sensing device 100, a line memory 200, an image signal processor (ISP) 300, an input/output (I/O) interface 400, and a data memory 500.

The image sensing device 100 may be a Complementary Metal Oxide Semiconductor Image Sensor (CIS) that converts optical signals into electrical signals. The overall operation of the image sensing device 100, such as on/off, operation mode, operation timing, sensitivity, and others, may be controlled by the ISP 300. The image sensing device 100 may transmit image data obtained by converting optical signals into electrical signals to the line memory 200 under the control of the ISP 300.

The line memory 200 may receive and store image data from the image sensing device 100, and transmit the stored image data to the ISP 300 under the control of the ISP 300. The line memory 200 may include volatile memory (e.g., DRAM, SRAM) and/or non-volatile memory (e.g., flash memory).

The ISP 300 may perform image signal processing on the image data stored in the line memory 200. The ISP 300 may reduce noise in the image data, and perform image signal processing for improving image quality, such as gamma correction, color filter array interpolation, color matrix, color correction, color enhancement, lens distortion correction, and others.

To generate an HDR image, the ISP 300 may include a gain processing unit 310 and an image composition unit 320.

The gain processing unit 310 may determine a gain operated on the image data (e.g., multiplication operation). The gain processing unit 310 may determine a gain based on the conversion gain difference between the high conversion gain (HCG) mode and the low conversion gain (LCG) mode, and provide the gain to the image compositing unit 320. Each pixel of the pixel array 110 may operate in the HCG mode or the LCG mode, and the mode of each pixel may be determined based on the received signal strength (or illuminance) of light entering each pixel.

The image compositing unit 320 may synthesize an HDR image corresponding to a high dynamic range using image data of pixels operating in the HCG mode and/or image data of pixels operating in the LCG mode.

The ISP 300 may transmit image signal-processed image data (e.g., HDR image) to the input/output interface 400.

As another example, the gain processing unit 310 and the image compositing unit 320 for generating an HDR image may be included in the image sensing device 100, rather than the ISP 300.

The input/output interface 400 may communicate with the host device 20 and transmit the image signal-processed image data to the host device 20.

The host device 20 may be a processor for processing the image signal-processed image data received from the imaging device 10. For example, the host device 20 may be an application processor, a memory (e.g., non-volatile memory) for storing image data, or a display device (e.g., liquid crystal display (LCD)) for visually outputting image data.

The data memory 500 may store image data of a digital format converted by an analog-digital converter (ADC).

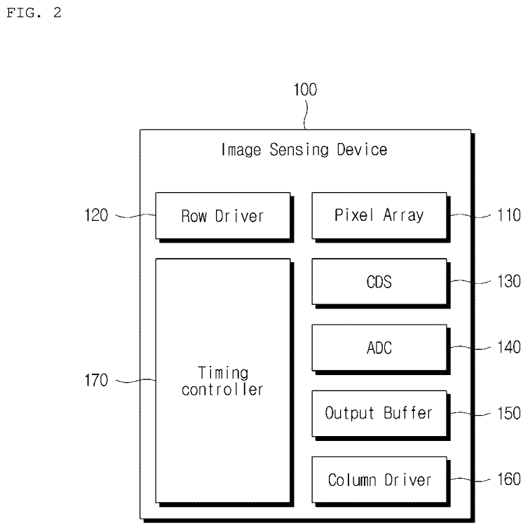

FIG. 2 is a block diagram showing an image sensing device of an imaging system based on an embodiment.

Referring to FIG. 2, the image sensing device 100 may include a pixel array 110, a row driver 120, a Correlate Double Sampler (CDS) 130, an analog-to-digital converter (ADC) 140, an output buffer 150, a column driver 160, and a timing controller 170. Here, each component of the image sensing device 100 is merely an example, and at least some components may be added or omitted as needed.

The pixel array 110 may include a plurality of image pixels arranged in a plurality of rows and a plurality of columns. For example, the image pixels may be arranged in a two-dimensional pixel array including rows and columns. As another example, the image pixels may be arranged in a three-dimensional pixel array. The image pixels may convert optical signals into electrical signals on a pixel basis or a pixel group basis, and image pixels in a pixel group may share at least some internal circuits. The pixel array 110 may receive a pixel control signal including a row selection signal, a pixel reset signal, a transfer signal, or others from the row driver 120, and a corresponding pixel that receives the pixel reset signal among the pixel array 110 may be activated to perform an operation corresponding to the row selection signal, pixel reset signal, or transfer signal. Each of the image pixels may detect incident light by generating photocharge corresponding to the strength (or illuminance) of the incident light and generating an electrical signal of a size corresponding to the quantity of the generated photocharge. Hereinafter, the image pixels may also be referred to as pixels for convenience of explanation.

The row driver 120 may activate the pixel array 110 to perform specific operations on pixels included in a corresponding row based on commands and control signals supplied by the timing controller 170.

The correlate double sampler 130 may sequentially sample and hold the reference signal and the image signal provided from the pixel array 110 to each of column lines. In operation, the correlate double sampler 130 may sample and hold the levels of the reference signal and the image signal corresponding to each of the columns of the pixel array 110. The correlate double sampler 130 may receive a control signal from the timing controller 170, and transfer the reference signal and the image signal of each of the columns to the ADC 140 as a correlate double sampling signal.

The ADC 140 may convert the correlate double sampling signal for each column output from the correlate double sampler 130 into a digital signal, and output image data. For example, the ADC 140 may receive a correlate double sampling signal for each of the columns from the correlate double sampler 130, convert the correlate double sampling signal into a digital signal, and output the digital signal.

The ADC 140 may include a plurality of column counters corresponding to the columns of the pixel array 110, respectively. Each column of the pixel array 110 may be connected to each column counter, and the column counters may generate image data by converting a correlated double sampling signal corresponding to each of the columns into a digital signal.

The output buffer 150 may temporarily hold and output each image data of column units provided from the ADC 140. The output buffer 150 may temporarily store image data output from the ADC 140 based on the control signal of the timing controller 170.

The column driver 160 may select a column of the output buffer 150 based on the control signal of the timing controller 170, and control the output buffer 150 to sequentially output the image data temporarily stored in the selected column.

The timing controller 170 may control at least one among the row driver 120, the correlate double sampler 130, the ADC 140, the output buffer 150, and the column driver 160.

The timing controller 170 may provide a clock signal required for the operation of each component of the image sensing device 100, a control signal for timing control, and an address signal for selecting a row or a column to at least one among the row driver 120, the correlate double sampler 130, the ADC 140, the output buffer 150, and the column driver 160. For example, the timing controller 170 may include a logic control circuit, a phase lock loop (PLL) circuit, a timing control circuit, and a communication interface circuit.

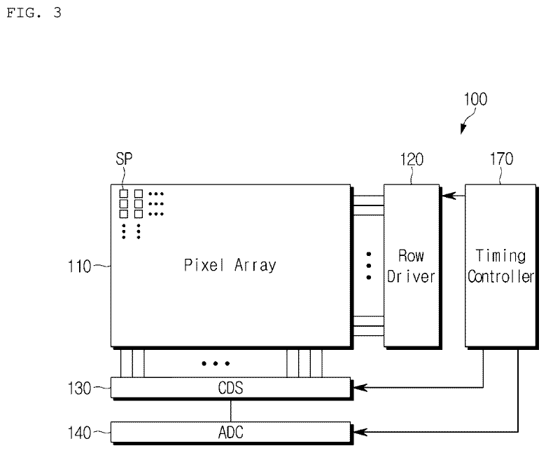

FIG. 3 is a view showing the connection relationship of an image sensing device of an imaging system based on an embodiment. Hereinafter, configurations identical to the configurations described above will be briefly described or omitted.

Referring to FIG. 3, the pixel array 110 may include a plurality of pixels SP. The pixels SP may be arranged in a matrix manner along the row direction and column direction, but the arrangement method of the pixels SP is not limited thereto. The pixels SP may include red pixels, green pixels, and blue pixels, but they are not limited thereto and may further include white pixels or infrared pixels.

The plurality of pixels SP may be electrically connected to the row driver 120. The plurality of pixels SP may be respectively connected to control lines extended from the row driver 120. The control lines may be transmission lines or boosting control lines, but they are not limited thereto.

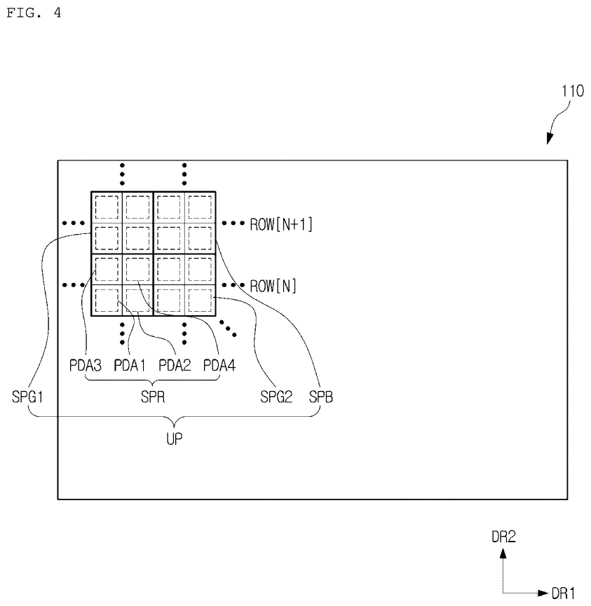

FIG. 4 is a plan view showing the pixel array in an imaging system based on an embodiment.

Referring to FIG. 4, the pixel array 110 may include a plurality of pixel groups UP. The plurality of pixel groups UP may be arranged in a first direction DR1 and a second direction DR2 intersecting the first direction DR1. Each of the pixel groups UP may include a first pixel SPR, a second pixel SPG1, a third pixel SPG2, and a fourth pixel SPB adjacent to each other.

The first pixel SPR may be arranged in the N-th row (ROW[N], where N is a positive integer). The first pixel SPR may be arranged in a direction opposite to the second direction DR2 of the second pixel SPG1 and may be arranged in a direction opposite to the first direction DR1 of the third pixel SPG2. For example, the first pixel SPR may be a red pixel, but it is not limited thereto.

The second pixel SPG1 may be arranged in the (N+1)-th row (ROW[N+1]). The (N+1)-th row (ROW[N+1]) may be arranged in the second direction DR2 of the N-th row ROW[N]. The second pixel SPG1 may be arranged in the second direction DR2 of the first pixel SPR and in a direction opposite to the first direction DR1 of the fourth pixel SPB. For example, the second pixel SPG1 may be a green pixel, but it is not limited thereto.

The third pixel SPG2 may be arranged in the N-th row ROW[N]. The third pixel SPG2 may be arranged in the first direction DR1 of the first pixel SPR and in a direction opposite to the second direction DR2 of the fourth pixel SPB. For example, the third pixel SPG2 may be a green pixel, but it is not limited thereto.

The fourth pixel SPB may be arranged in the (N+1)-th row (ROW[N+1]). The fourth pixel SPB may be arranged in the first direction DR1 of the second pixel SPG1 and in the second direction DR2 of the third pixel SPG2. For example, the fourth pixel SPB may be a blue pixel, but it is not limited thereto. The arrangement relationship of the first to fourth pixels SPR, SPG1, SPG2, and SPB is not limited as shown in FIG. 4.

In implementations for color imaging, each pixel group UP may include different pixels for sensing light of different colors so the different pixels within each pixel group UP can collectively obtain coloring information for each pixel group UP. For example, the Bayer color pattern may be used to implement 4 color filters in the four pixels within each pixel group UP: two pixels with color filters in green to detect the portion of the incident light in green only, one pixel with a color filter in red to detect the portion in the incident light in red only, and one pixel with a color filter in blue to detect the portion of incident light in blue only. Such a Bayer filter pattern enables each pixel group UP to interpret the color information in the incident light for color imaging.

A pixel SP may include at least one light detection region and a circuit region overlapping the light detection region. The light detection region may include a photodetector, and the circuit region may include a pixel circuit electrically connected to the photodetector. Each of the first to fourth pixels SPR, SPG1, SPG2, and SPB may include first to fourth light detection regions PDA1, PDA2, PDA3, and PDA4.

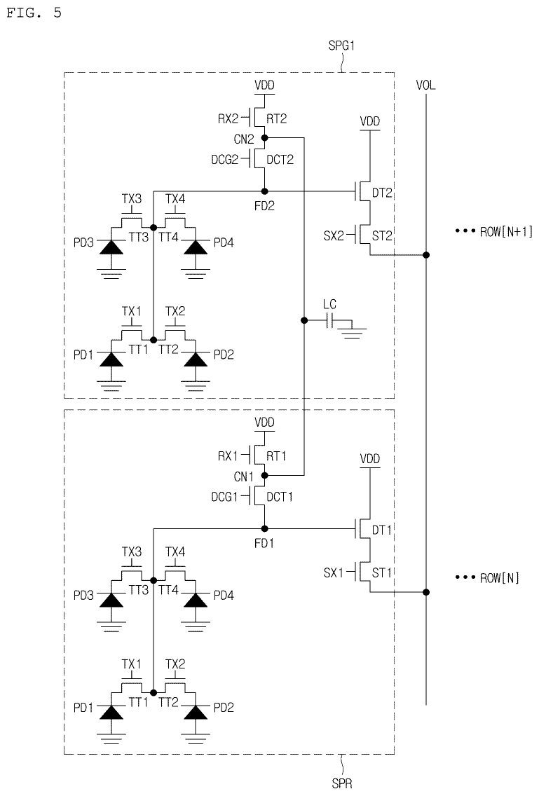

FIG. 5 is a circuit diagram showing pixels of an imaging system based on an embodiment.

Referring to FIG. 5, the first pixel SPR may be arranged in the N-th row ROW[N], and the second pixel SPG1 may be arranged in the N+1-th row ROW[N+1]. The first pixel SPR may include first to fourth photodetectors PD1, PD2, PD3, and PD4, first to fourth transfer transistors TT1, TT2, TT3, and TT4, a first reset transistor RT1, a first driving transistor DT1, and a first selection transistor ST1. The second pixel SPG1 may include first to fourth photodetectors PD1, PD2, PD3, and PD4, first to fourth transfer transistors TT1, TT2, TT3, and TT4, a second reset transistor RT2, a second driving transistor DT2, and a second selection transistor ST2.

The first pixel SPR may include a first floating diffusion region FD1 and a first dual conversion gain (DCG) transistor DCT1, and the second pixel SPG1 may include a second floating diffusion region FD2 and a second DCG transistor DCT2. Hereinafter, the configuration of the first pixel SPR will be described, and identical configurations in the second pixel SPG1 will be briefly described or omitted.

Each of the first to fourth photodetectors PD1, PD2, PD3, and PD4 may generate and accumulate photocharge corresponding to intensity of incident light. For example, the first to fourth photodetectors PD1, PD2, PD3, and PD4 may be implemented as a photodiode, a phototransistor, a photogate, a pinned photodiode, or a combination thereof. When the first to fourth photodetectors PD1, PD2, PD3, and PD4 are implemented as a photodiode, it may be a region doped with impurities of a second conductivity type (e.g., N type) in a substrate having a first conductivity type (e.g., P type). The first to fourth photodetectors PD1, PD2, PD3, and PD4 may be photodetectors for detecting a phase. The number of photodetectors of each of the first and second pixels SPR and SPG1 is not limited as shown in FIG. 5.

The first transfer transistor TT1 of the first pixel SPR may be connected between the first photodetector PD1 and the first floating diffusion region FD1. The first transfer transistor TT1 may be turned on in response to the first transfer signal TX1 and transfer the photocharge accumulated in the first photodetector PD1 to the first floating diffusion region FD1. The gate electrode of the first transfer transistor TT1 may receive the first transfer signal TX1, the drain electrode of the first transfer transistor TT1 may be connected to the first floating diffusion region FD1, and the source electrode of the first transfer transistor TT1 may be connected to the first photodetector PD1.

The second transfer transistor TT2 of the first pixel SPR may be connected between the second photodetector PD2 and the first floating diffusion region FD1. The second transfer transistor TT2 may be turned on in response to the second transfer signal TX2 and transfer the photocharge accumulated in the second photodetector PD2 to the first floating diffusion region FD1. The gate electrode of the second transfer transistor TT2 may receive the second transfer signal TX2, the drain electrode of the second transfer transistor TT2 may be connected to the first floating diffusion region FD1, and the source electrode of the second transfer transistor TT2 may be connected to the second photodetector PD2.

The third transfer transistor TT3 of the first pixel SPR may be connected between the third photodetector PD3 and the first floating diffusion region FD1. The third transfer transistor TT3 may be turned on in response to the third transfer signal TX3 and transfer the photocharge accumulated in the third photodetector PD3 to the first floating diffusion region FD1. The gate electrode of the third transfer transistor TT3 may receive the third transfer signal TX3, the drain electrode of the third transfer transistor TT3 may be connected to the first floating diffusion region FD1, and the source electrode of the third transfer transistor TT3 may be connected to the third photodetector PD3.

The fourth transfer transistor TT4 of the first pixel SPR may be connected between the fourth photodetector PD4 and the first floating diffusion region FD1. The fourth transfer transistor TT4 may be turned on in response to the fourth transfer signal TX4 and transfer the photocharge accumulated in the fourth photodetector PD4 to the first floating diffusion region FD1. The gate electrode of the fourth transfer transistor TT4 may receive the fourth transfer signal TX4, the drain electrode of the fourth transfer transistor TT4 may be connected to the first floating diffusion region FD1, and the source electrode of the fourth transfer transistor TT4 may be connected to the fourth photodetector PD4.

The reset transistor RT1 of the first pixel SPR may be connected between the power supply voltage VDD and a first connection node CN1 that connects the first pixel SPR to a corresponding second connection node CN2 in the second pixel SPG1. The reset transistor RT1 may reset the voltage of the connection node CN1 to the power supply voltage VDD in response to a reset signal RX. The gate electrode of the reset transistor RT1 may receive the reset signal RX, the drain electrode of the reset transistor RT1 may receive the power supply voltage VDD, and the source electrode of the reset transistor RT1 may be connected to the connection node CN1. In some implementations, the term “connection node” can refer to a shared electrical node in an image sensor where signals from a plurality of pixels may be controlled to be either combined or transferred for readout together or separately readout.

The first DCG transistor DCT1 of the first pixel SPR may be connected between the connection node CN1 and the first floating diffusion region FD1. The first DCG transistor DCT1 may supply the voltage of the connection node CN1 to the first floating diffusion region FD1 in response to a first DCG signal DCG1. The first DCG transistor DCT1 may be turned off or turned on in a high conversion gain (HCG) mode or a low conversion gain (LCG) mode. For example, the first DCG transistor DCT1 may be turned off in the HCG mode and turned on in the LCG mode. The voltage of the first floating diffusion region FD1 may be determined by the amount of photocharge transferred through the first to fourth transfer transistors TT1, TT2, TT3, and TT4 within the first pixel SPR, and as the amount of photocharge increases, the voltage of the first floating diffusion region FD1 may be lowered. The gate electrode of the first DCG transistor DCT1 may receive the first DCG signal DCG1, the drain electrode of the first DCG transistor DCT1 may be connected to the connection node CN1, and the source electrode of the first DCG transistor DCT1 may be connected to the first floating diffusion region FD1.

The first floating diffusion region FD1 may accumulate photocharge generated by and transferred from the first to fourth photodetectors PD1, PD2, PD3, and PD4 within the first pixel SPR. For example, the first floating diffusion region FD1 may be a region doped with impurities of a second conductivity type (e.g., N type) in a substrate having a first conductivity type (e.g., P type), and the substrate and the region doped with impurities may be modeled as a junction capacitor. The first floating diffusion region FD1 may be connected to the drain electrodes of the first to fourth transfer transistors TT1, TT2, TT3, and TT4, the source electrode of the first DCG transistor DCT1, and the gate electrode of the first driving transistor DT1. The first floating diffusion region FD1 may include a first floating diffusion electrode (not shown).

The connection node CN1 of the first pixel SPR and the corresponding connection node CN2 of the second pixel SPG1 may be electrically connected to enable using the combined charge holding capacity of both pixels SPR and SPG1 associated with their floating diffusion electrodes FD1 and FD2 for readout without signal loss when the incident light has a high optical intensity. The first and second pixels SPR and SPG1 may share the first and second connection nodes CN1, CN2. The voltage of the first and second connection nodes CN1, CN2 may be stored in a line capacitor LC. In the case of sensing incident light of the first pixel SPR, electrostatic capacitance of the line capacitor LC and the second floating diffusion region FD2 of the second pixel SPG1 may be additionally provided through the first and second connection nodes CN1, CN2. In the case of sensing incident light of the second pixel SPG1, electrostatic capacitance of the line capacitor LC and the first floating diffusion region FD1 of the first pixel SPR may be additionally provided through the first and second connection nodes CN1, CN2. In some implementations, the term “line capacitor” can refer to a capacitor that is connected to the connection node and is used to store or stabilize the voltage at the node during signal readout.

Each of the first and second pixels SPR and SPG1 includes the first to fourth photodetectors PD1, PD2, PD3, and PD4, and thus may accumulate a relatively large amount of photocharge. When the respective connection nodes CN1 and CN2 of the first and second pixels SPR and SPG1 are not connected to each other, all the photocharge accumulated in the first to fourth photodetectors PD1, PD2, PD3, and PD4 in one of the first pixel SPR or second pixel SPG1 may exceed the charge holding capacity of one floating diffusion region for that pixel alone and, as a result, the excessive photocharge generated in one of the first pixel SPR or second pixel SPG1 beyond the charge holding capacity of one pixel may flow to the power supply voltage VDD through adjacent transistors. In such a situation, the generated excessive photocharge is not captured for detection to cause undesired signal loss, and thus light detection sensitivity of the image sensing device 100 may be lowered, and the reliability of the imaging device 10 may be degraded. Alternatively, if a connection is provided in the image sensing device 100 to connect between the connection nodes CN1 and CN2 of the first and second pixels SPR and SPG1 so that the connection nodes CN1 and CN2 can be linked to each other and thus shared by the first pixel SPR and second pixel SPG1, the charge holding storage capacities of FD1 and FD2 of the two pixels can be combined together to provide sufficient electrostatic capacitance even when the first to fourth photodetectors PD1, PD2, PD3, and PD4 are saturated, and enhance reliability of the imaging device 10 by improving light detection sensitivity of the image sensing device 100.

The driving transistor DT1 is connected between the power supply voltage VDD and the selection transistor ST1, and may amplify a change in the electric voltage of the first floating diffusion region FD1 and transmit it to the selection transistor ST2. The gate electrode of the driving transistor DT1 of the first pixel SPR is connected to the first floating diffusion region FD1, the drain electrode of the driving transistor DT1 receives the power supply voltage VDD, and the source electrode of the driving transistor DT1 may be connected to the drain electrode of the selection transistor ST1.

Within the first pixel SGR, the selection transistor ST1 may be connected between the driving transistor DT1 and the output line VOL. The selection transistor ST1 may receive an electrical signal from the driving transistor DT1 and supply an output voltage to the output line VOL in response to a selection signal SX. Different pixels SP arranged in the same column may be connected to the same output line VOL. Therefore, the first and second pixels SPR and SPG1 may be connected to one output line VOL. The gate electrode of the selection transistor ST1 may receive the selection signal SX, the drain electrode of the selection transistor ST1 may be connected to the source electrode of the driving transistor DT1, and the source electrode of the selection transistor ST1 may be connected to the output line VOL.

The second pixel SPG1 may include the second floating diffusion region FD2 that is separate from the first floating diffusion region FD1 of the first pixel SPR, and may include the second DCG transistor DCT2 that receives a second DCG signal DCG2 instead of the first DCG transistor DCT1 of the first pixel SPR. Other configurations of the second pixel SPG1, including CN2, RT2, DT2 and ST2, may be the same as those corresponding components of the first pixel SPR.

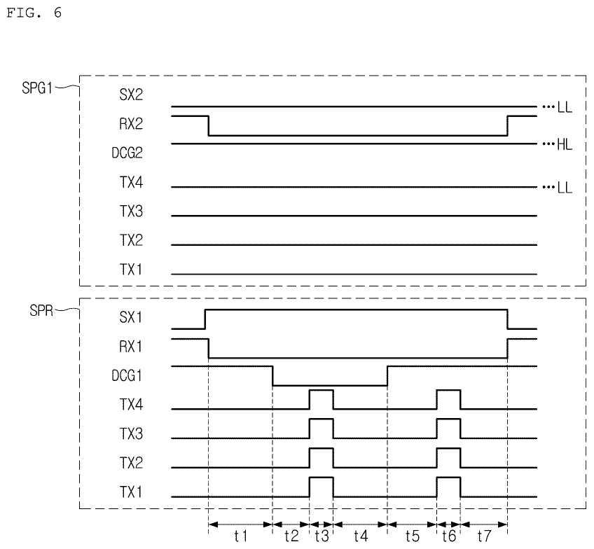

FIG. 6 is a waveform diagram showing signals in a light detection process of a first pixel among the pixels of FIG. 5.

Referring FIG. 6 in connection with FIG. 5, the first and second pixels SPR and SPG1 may sequentially detect light. While the first pixel SPR arranged in the N-th row ROW[N] detects light, the second pixel SPG1 arranged in the N+1-th row ROW[N+1] may not detect light. The first selection transistor ST1 of the first pixel SPR may receive a first selection signal SX1 of high level during the first to seventh periods t1 to t7, and the first selection transistor ST1 may be turned on and supply an output voltage to the output line VOL. Here, the first to seventh periods t1 to t7 may be periods that proceed sequentially. The first pixel SPR may provide the output voltage to the output line VOL based on incident light of the first to fourth photodetectors PD1, PD2, PD3, and PD4. The second selection transistor ST2 of the second pixel SPG1 may receive a selection signal SX of low level LL during the first to seventh periods t1 to t7.

The first reset transistors RT1 of the first pixel SPR may receive a first reset signal RX1 of low level during the first to seventh periods t1 to t7. The second reset transistors RT2 of the second pixel may receive a second reset signal RX2 of low level during the first to seventh periods t1 to t7. The first reset transistor RT1 of the first pixel SPR may receive the first reset signal RX1 of high level before the first period t1 and reset the voltage of the first connection node CN1 to the power supply voltage VDD. The second reset transistor RT2 of the second pixel SPG1 may receive the second reset signal RX2 of high level before the first period t1 and reset the voltage of the second connection node CN2 to the power supply voltage VDD.

The first DCG transistor DCT1 may receive the first DCG signal DCG1 of low level during the second to fourth periods t2, t3, and t4. The first pixel SPR may operate in the HCG mode during the second to fourth periods t2, t3, and t4, and supply an output voltage for the HCG mode to the output line VOL. The first DCG transistor DCT1 may receive the first DCG signal DCG1 of high level during the first, fifth to seventh periods t1, t5 to t7. The first pixel SPR may operate in the LCG mode during the fifth to seventh periods t5, t6, and t7, and supply an output voltage for the LCG mode to the output line VOL.

The second DCG transistor DCT2 may receive the second DCG signal DCG2 of high level HL during the first to seventh periods t1 to t7. As the second DCG transistor DCT2 is turned on during the first to seventh periods t1 to t7, electrostatic capacitance of the line capacitor LC and the second floating diffusion region FD2 may be additionally provided.

The first to fourth transfer transistors TT1, TT2, TT3, and TT4 of the first pixel SPR may receive the first to fourth transfer signals TX1, TX2, TX3, and TX4 of high level during the third period t3, respectively. As the first to fourth transfer transistors TT1, TT2, TT3, and TT4 are turned on during the third period t3, the photocharge accumulated in the first to fourth photodetectors PD1, PD2, PD3, and PD4 for the HCG mode may be transferred to the first floating diffusion region FD1. The first DCG transistor DCT1 may be turned off in the HCG mode, and electrostatic capacitance of the first floating diffusion region FD1 may be insufficient to accumulate photocharge. The image sensing device 100 may provide additional electrostatic capacitance and prevent the photocharge from flowing to other regions by connecting the first and second connection nodes CN1, CN2 of the first and second pixels SPR and SPG1 and turning on the second DCG transistor DCT2. Accordingly, light detection sensitivity of the image sensing device 100 can be improved, and reliability of the imaging device 10 can be enhanced.

The first to fourth transfer transistors TT1, TT2, TT3, and TT4 of the first pixel SPR may receive the first to fourth transfer signals TX1, TX2, TX3, and TX4 of high level during the sixth period t6, respectively. As the first to fourth transfer transistors TT1, TT2, TT3, and TT4 are turned on during the sixth period t6, the photocharge accumulated in the first to fourth photodetectors PD1, PD2, PD3, and PD4 for the LCG mode may be transferred to the first floating diffusion region FD1. As the first and second DCG transistors DCT1 and DCT2 are turned on in the LCG mode, the first and second floating diffusion regions FD1 and FD2 and the line capacitor LC may sufficiently accommodate the photocharge accumulated in the first to fourth photodetectors PD1, PD2, PD3, and PD4. Accordingly, the image sensing device 100 may improve light detection sensitivity and enhance reliability of the imaging device 10 by preventing the photocharge from flowing into other regions.

The first to fourth transfer transistors TT1, TT2, TT3, and TT4 of the second pixel SPG1 may receive the first to fourth transfer signals TX1, TX2, TX3, and TX4 of low level LL during the first to seventh periods t1 to t7, respectively.

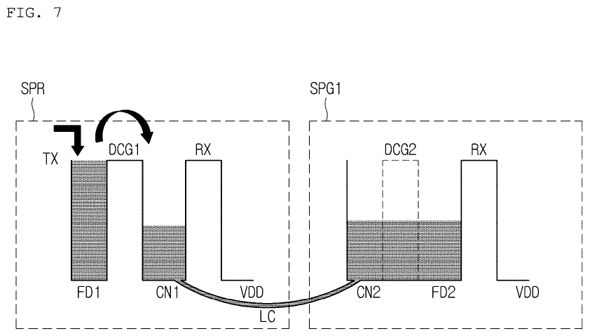

FIG. 7 is a view showing voltages of first and second pixels in the HCG mode of an imaging system based on an embodiment. FIG. 7 may show a path through which the photocharge of the first pixel SPR is transferred to the second pixel SPG1.

Referring to FIG. 7, the photocharge accumulated in the first to fourth photodetectors PD1, PD2, PD3, and PD4 may be transferred to the first floating diffusion region FD1 by the first to fourth transfer transistors TT1, TT2, TT3, and TT4 that receive the transfer signals TX. As the photocharge accumulates, the voltage may increase. The first DCG transistor DCT1 may be turned off in the HCG mode, and the second DCG transistor DCT2 may be turned on in the HCG mode. Electrostatic capacitance of the first floating diffusion region FD1 may be insufficient to accumulate the photocharge of the first to fourth photodetectors PD1, PD2, PD3, and PD4. Some of the photocharge not accommodated in the first floating diffusion region FD1 may flow through the first DCG transistor DCT1 and be accumulated in the first connection node CN1 of the first pixel SPR. The first connection node CN1 of the first pixel SPR and the second connection node CN2 of the second pixel SPG1 may be electrically connected. The voltage of the first and second connection nodes CN1, CN2 may be stored in the line capacitor LC. The photocharge of the first pixel SPR may be transferred to the second floating diffusion region FD2 of the second pixel SPG1 through the first and second connection nodes CN1, CN2. Therefore, the photocharge of the first to fourth photodetectors PD1, PD2, PD3, and PD4 may be accumulated in the first floating diffusion region FD1, the first connection node CN1 of the first pixel SPR, the line capacitor LC, the second connection node CN2 of the second pixel SPG1, and the second floating diffusion region FD2.

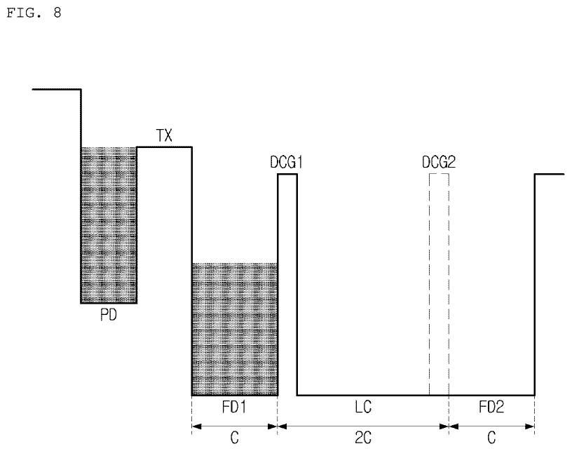

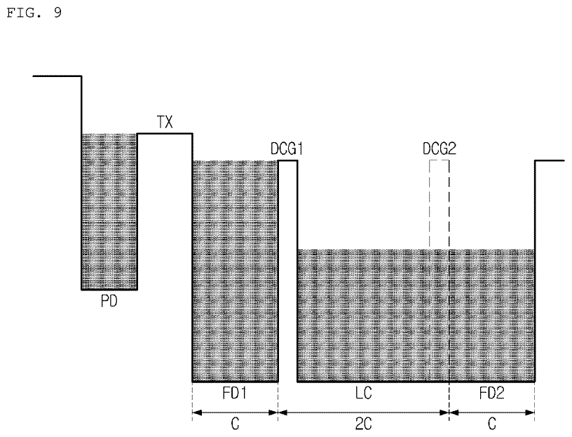

FIG. 8 is a view showing an example of voltages of the first and second floating diffusion regions and the line capacitor in the HCG mode of an imaging system based on an embodiment, and FIG. 9 is a view showing another example of voltages of the first and second floating diffusion regions and the line capacitor in the HCG mode of an imaging system based on an embodiment. FIGS. 8 and 9 show the capacity of electrostatic capacitance of the first floating diffusion region FD1, the line capacitor LC, and the second floating diffusion region FD2, and the capacity of electrostatic capacitance is not limited as shown in FIGS. 8 and 9.

Referring to FIGS. 8 and 9, the photocharge accumulated in the photodetectors PD may be transferred to the first floating diffusion region FD1 by the first to fourth transfer transistors TT1, TT2, TT3, and TT4 that receive the transfer signals TX. The line capacitor LC may store the voltage of the first and second connection nodes CN1, CN2 of the first and second pixels SPR and SPG1. Electrostatic capacitance of the line capacitor LC shown in FIGS. 8 and 9 may include electrostatic capacitance of the first and second connection nodes CN1, CN2.

The first DCG transistor DCT1 may be turned off in the HCG mode, and the second DCG transistor DCT2 may be turned on in the HCG mode. The capacity C of electrostatic capacitance of the first floating diffusion region FD1 may be substantially the same as the capacity C of electrostatic capacitance of the second floating diffusion region FD2. The capacity 2C of electrostatic capacitance of the line capacitor LC may be twice the capacity C of electrostatic capacitance of the first floating diffusion region FD1. Here, the capacity C of electrostatic capacitance of the first floating diffusion region FD1 may accommodate photocharge saturated in one of the first to fourth photodetectors PD1, PD2, PD3, and PD4. Therefore, the sum of the electrostatic capacitance of the first floating diffusion region FD1, the line capacitor LC, and the second floating diffusion region FD2 may accommodate all photocharge saturated in the first to fourth photodetectors PD1, PD2, PD3, and PD4 for signal detection.

In FIG. 8, when the amount of photocharge accumulated in the first to fourth photodetectors PD1, PD2, PD3, and PD4 is smaller than the amount of photocharge saturated in one of the first to fourth photodetectors PD1, PD2, PD3, and PD4, the photocharge may be accommodated in the first floating diffusion region FD1. In FIG. 9, when the amount of photocharge accumulated in the first to fourth photodetectors PD1, PD2, PD3, and PD4 is greater than the amount of photocharge saturated in one of the first to fourth photodetectors PD1, PD2, PD3, and PD4, the photocharge may flow through the first DCG transistor DCT1 and be accommodated in the line capacitor LC and the second floating diffusion region FD2. Accordingly, the image sensing device 100 may provide sufficient electrostatic capacitance even when the first to fourth photodetectors PD1, PD2, PD3, and PD4 are saturated, and enhance reliability of the imaging device 10 by improving light detection sensitivity of the image sensing device 100.

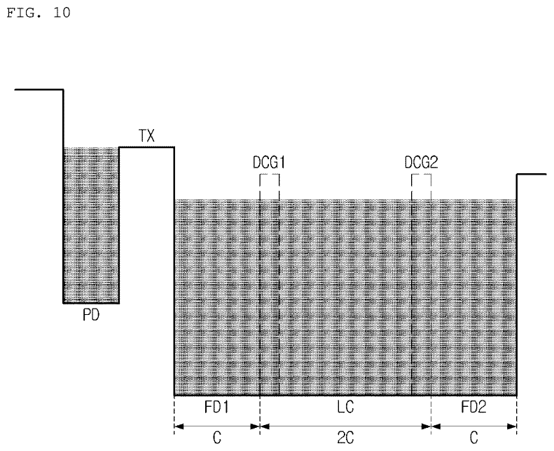

FIG. 10 is a view showing voltages of the first and second floating diffusion regions and the line capacitor in the LCG mode of an imaging system based on an embodiment. FIG. 10 shows the capacity of electrostatic capacitance of the first floating diffusion region FD1, the line capacitor LC, and the second floating diffusion region FD2, and the capacity of electrostatic capacitance is not limited as shown in FIG. 10.

Referring to FIG. 10, the photocharge accumulated in the photodetectors PD may be transferred to the first floating diffusion region FD1 by the first to fourth transfer transistors TT1, TT2, TT3, and TT4 that receive the transfer signals TX. The line capacitor LC may store the voltage of the first and second connection nodes CN1, CN2 of the first and second pixels SPR and SPG1. Electrostatic capacitance of the line capacitor LC shown in FIG. 10 may include electrostatic capacitance of the first and second connection nodes CN1, CN2.

The first and second DCG transistors DCT1 and DCT2 may be turned on in the LCG mode. The photocharge accumulated in the first to fourth photodetectors PD1, PD2, PD3, and PD4 may be accommodated in the line capacitor LC and the second floating diffusion region FD2 through the turned-on first and second DCG transistors DCT1 and DCT2. Accordingly, the image sensing device 100 may provide sufficient electrostatic capacitance even when the first to fourth photodetectors PD1, PD2, PD3, and PD4 are saturated, and enhance reliability of the imaging device 10 by improving light detection sensitivity of the image sensing device 100.

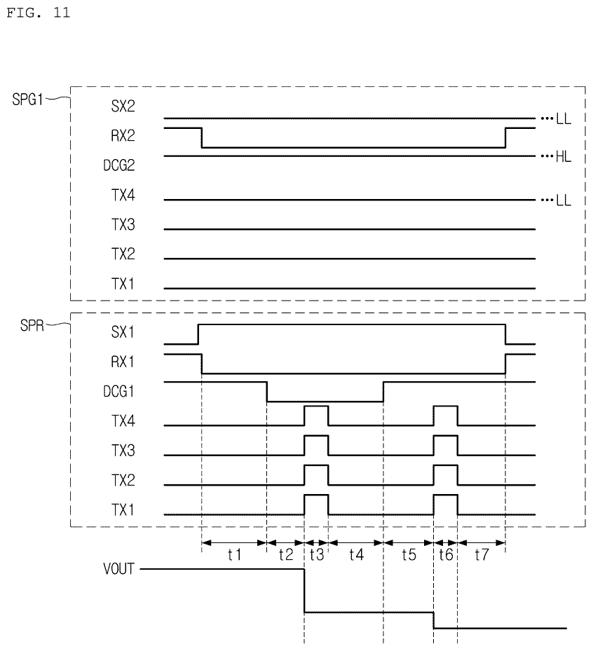

FIG. 11 is a waveform diagram showing output voltage of a first pixel in an imaging system based on an embodiment.

Referring to FIG. 11, as the first to fourth transfer transistors TT1, TT2, TT3, and TT4 are turned on during the third period t3, the photocharge accumulated in the first to fourth photodetectors PD1, PD2, PD3, and PD4 for the HCG mode may be transferred to the first floating diffusion region FD1. The voltage of the first floating diffusion region FD1 may be determined by the amount of photocharge transferred through the first to fourth transfer transistors TT1, TT2, TT3, and TT4, and as the amount of photocharge increases, the voltage of the first floating diffusion region FD1 may be lowered. The first driving transistor DT1 and the first selection transistor ST1 may be turned on during the third period t3, and the output voltage VOUT may be supplied to the output line VOL. The magnitude of the output voltage VOUT may be primarily decreased by the HCG mode after the third period t3.

As the first to fourth transfer transistors TT1, TT2, TT3, and TT4 are turned on during the sixth period t6, the photocharge accumulated in the first to fourth photodetectors PD1, PD2, PD3, and PD4 for the LCG mode may be transferred to the first floating diffusion region FD1. The first driving transistor DT1 and the first selection transistor ST1 may be turned on during the sixth period t6, and the output voltage VOUT may be supplied to the output line VOL. The magnitude of the output voltage VOUT may be secondarily decreased by the LCG mode after the sixth period t6. Therefore, the imaging device 10 may generate an image by determining a gain based on the difference in conversion gain between the HCG mode and the LCG mode.

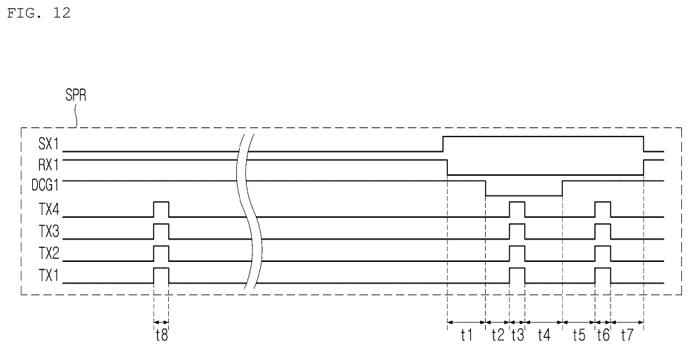

FIG. 12 is a waveform diagram showing reset periods of photodetectors of a first pixel in an imaging system based on an embodiment.

Referring to FIG. 12, the first to fourth transfer transistors TT1, TT2, TT3, and TT4 of the first pixel SPR may receive the first to fourth transfer signals TX1, TX2, TX3, and TX4 of high level during then eighth period t8, respectively. Here, the eighth period t8 may precede the first to seventh periods t1 to t7. The eighth period t8 may be a reset period of the photodetector. Therefore, the first to fourth photodetectors PD1, PD2, PD3, and PD4 may be reset during the eighth period t8 to initialize the accumulated photocharge.

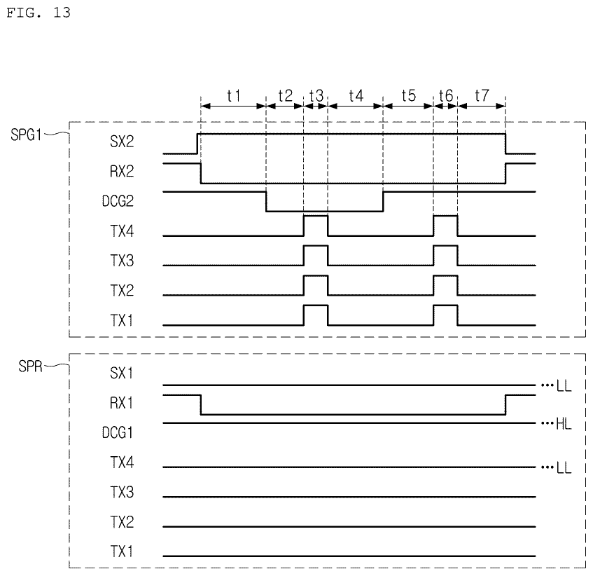

FIG. 13 is a waveform diagram showing signals in the light detection process of a second pixel among the pixels of FIG. 5.

Referring to FIG. 13 in connection with FIG. 5, the first and second pixels SPR and SPG1 may sequentially detect light. After the first pixel SPR arranged in the N-th row ROW[N] detects light, the second pixel SPG1 arranged in the N+1-th row ROW[N+1] may detect light. While the second pixel SPG1 arranged in the N+1-th row ROW[N+1] detects light, the first pixel SPR arranged in the N-th row ROW[N] may not detect light.

The second selection transistor ST2 of the second pixel SPG1 may receive a second selection signal SX2 of high level during the first to seventh periods t1 to t7, and the second selection transistor ST2 may be turned on and supply an output voltage to the output line VOL. The first selection transistor ST1 of the first pixel SPR may receive a selection signal SX of low level LL during the first to seventh periods t1 to t7.

The first and second reset transistors RT1, RT2 of the first and second pixels SPR and SPG1 may receive a first and second reset signals RX1, RX2 of low level during the first to seventh periods t1 to t7. The first and second reset transistors RT1, RT2 of the first and second pixels SPR and SPG1 may receive the first and second reset signals RX1, RX2 of high level before the first period t1 and reset the voltage of the first and second connection nodes CN1, CN2 to the power supply voltage VDD.

The second DCG transistor DCT2 may receive the second DCG signal DCG2 of low level during the second to fourth periods t2, t3, and t4. The second pixel SPG1 may operate in the HCG mode during the second to fourth periods t2, t3, and t4, and supply an output voltage for the HCG mode to the output line VOL. The second DCG transistor DCT2 may receive the second DCG signal DCG2 of high level during the first, fifth to seventh periods t1, t5 to t7. The second pixel SPG1 may operate in the LCG mode during the fifth to seventh periods t5, t6, and t7, and supply an output voltage for the LCG mode to the output line VOL.

The first DCG transistor DCT1 may receive the first DCG signal DCG1 of high level HL during the first to seventh periods t1 to t7. As the first DCG transistor DCT1 is turned on during the first to seventh periods t1 to t7, electrostatic capacitance of the line capacitor LC and the first floating diffusion region FD1 may be additionally provided.

The first to fourth transfer transistors TT1, TT2, TT3, and TT4 of the second pixel SPG1 may receive the first to fourth transfer signals TX1, TX2, TX3, and TX4 of high level during the third period t3, respectively. As the first to fourth transfer transistors TT1, TT2, TT3, and TT4 are turned on during the third period t3, the photocharge accumulated in the first to fourth photodetectors PD1, PD2, PD3, and PD4 for the HCG mode may be transferred to the second floating diffusion region FD2. The second DCG transistor DCT2 may be turned off in the HCG mode, and electrostatic capacitance of the second floating diffusion region FD2 may be insufficient to accumulate photocharge. The image sensing device 100 may provide additional electrostatic capacitance and prevent the photocharge from flowing to other regions by connecting the first and second connection nodes CN1, CN2 of the first and second pixels SPR and SPG1 and turning on the first DCG transistor DCT1. Accordingly, light detection sensitivity of the image sensing device 100 can be improved, and reliability of the imaging device 10 can be enhanced.

The first to fourth transfer transistors TT1, TT2, TT3, and TT4 of the second pixel SPG1 may receive the first to fourth transfer signals TX1, TX2, TX3, and TX4 of high level during the sixth period t6, respectively. As the first to fourth transfer transistors TT1, TT2, TT3, and TT4 are turned on during the sixth period t6, the photocharge accumulated in the first to fourth photodetectors PD1, PD2, PD3, and PD4 for the LCG mode may be transferred to the second floating diffusion region FD2. As the first and second DCG transistors DCT1 and DCT2 are turned on in the LCG mode, the first and second floating diffusion regions FD1 and FD2 and the line capacitor LC may sufficiently accommodate the photocharge accumulated in the first to fourth photodetectors PD1, PD2, PD3, and PD4. Accordingly, the image sensing device 100 may improve light detection sensitivity and enhance reliability of the imaging device 10 by preventing the photocharge from flowing into other regions.

The first to fourth transfer transistors TT1, TT2, TT3, and TT4 of the first pixel SPR may receive the first to fourth transfer signals TX1, TX2, TX3, and TX4 of low level LL during the first to seventh periods t1 to t7.

The image sensing device 100 and the imaging device 10 including the same based on various embodiments of the disclosed technology may be described as follows.

An image sensing device based on various embodiments of the disclosed technology includes a first pixel including a connection node, a second pixel arranged to be adjacent to the first pixel to share the connection node, and a line capacitor for storing a voltage of the connection node. The first pixel includes at least one photodetector, a first floating diffusion region that receives charges accumulated in the at least one photodetector, and a first dual conversion gain (DCG) transistor arranged between the first floating diffusion region and the connection node, and the second pixel includes a second floating diffusion region that receives charges accumulated in the at least one photodetector through the line capacitor, and a second DCG transistor arranged between the connection node and the second floating diffusion region.

In an image sensing device based on various embodiments of the disclosed technology, the first DCG transistor may be turned off in a first mode, and the second DCG transistor may be turned on in the first mode.

In an image sensing device based on various embodiments of the disclosed technology, when the amount of photocharge accumulated in the at least one photodetector in the first mode is greater than the capacitance of the first floating diffusion region, the photocharge accumulated in the at least one photodetector may flow through the first DCG transistor and be accumulated in the line capacitor and the second floating diffusion region.

In an image sensing device based on various embodiments of the disclosed technology, the first DCG transistor may be turned on in a second mode, and the second DCG transistor may be turned on in the second mode.

In an image sensing device based on various embodiments of the disclosed technology, the photocharge accumulated in the at least one photodetector in the second mode may be accumulated in the first floating diffusion region, the line capacitor, and the second floating diffusion region.

An image sensing device based on various embodiments of the disclosed technology may further include an output line connected to the first and second pixels. The first pixel may further include a driving transistor turned on in response to the voltage of the first floating diffusion region, and a selection transistor electrically connecting the driving transistor and the output line, and the second pixel may further include a driving transistor turned on in response to the voltage of the second floating diffusion region, and a selection transistor electrically connecting the driving transistor and the output line.

In an image sensing device based on various embodiments of the disclosed technology, the selection transistor of the first pixel may be turned on in the first and second modes, and the selection transistor of the second pixel may be turned off in the first and second modes.

In an image sensing device based on various embodiments of the disclosed technology, the first pixel further includes at least one transfer transistor one-to-one corresponding to the at least one photodetector to transfer charges accumulated in the at least one photodetector to the first floating diffusion region, and the at least one transfer transistor may be turned on in each of the first and second modes.

In an image sensing device based on various embodiments of the disclosed technology, each of the first pixel and the second pixel further includes a reset transistor for supplying a power voltage to the connection node based on a reset signal, and the reset transistor of each of the first and second pixels may be turned off in the first and second modes.

In an image sensing device based on various embodiments of the disclosed technology, electrostatic capacitance of the line capacitor may be greater than electrostatic capacitance of the first floating diffusion region or electrostatic capacitance of the second floating diffusion region.

In an image sensing device based on various embodiments of the disclosed technology, the at least one photodetector may include a plurality of photodetectors, and capacitance of the first floating diffusion region may be lower than the amount of charge saturated in the plurality of photodetectors.

In an image sensing device based on various embodiments of the disclosed technology, the first pixel may be arranged in a first row, and the second pixel may be arranged in a second row adjacent to the first row.

An image sensing device based on various embodiments of the disclosed technology includes a first pixel arranged in a first row, and a second pixel arranged in a second row adjacent to the first row and electrically connected to the first pixel through a connection node. The first pixel includes at least one photodetector, a first floating diffusion region that receives charges accumulated in the at least one photodetector, and a first dual conversion gain (DCG) transistor arranged between the first floating diffusion region and the connection node and turned off in a first mode and turned on in a second mode, and the second pixel includes a second floating diffusion region that receives charges accumulated in the at least one photodetector, and a second DCG transistor arranged between the connection node and the second floating diffusion region and turned on in the first mode and the second mode.

In an image sensing device based on various embodiments of the disclosed technology, each of the first pixel and the second pixel further includes a reset transistor for supplying a power voltage to the connection node based on a reset signal, and the reset transistor of each of the first and second pixels may be turned off during the first to seventh periods that proceed sequentially.

In an image sensing device based on various embodiments of the disclosed technology, the first DCG transistor may be turned off during the second to fourth periods and turned on during the first, fifth to seventh periods, and the second DCG transistor may be turned on during the first to seventh periods.

In an image sensing device based on various embodiments of the disclosed technology, the image sensing device may further include an output line connected to the first and second pixels. The first pixel may further include a driving transistor turned based on the voltage of the first floating diffusion region, and a selection transistor electrically connecting the driving transistor and the output line, and the second pixel may further include a driving transistor turned based on the voltage of the second floating diffusion region, and a selection transistor electrically connecting the driving transistor and the output line.

In an image sensing device based on various embodiments of the disclosed technology, the selection transistor of the first pixel may be turned on during the first to seventh periods, and the selection transistor of the second pixel may be turned off during the first to seventh periods.

In an image sensing device based on various embodiments of the disclosed technology, the first pixel further includes at least one transfer transistor one-to-one corresponding to the at least one photodetector to transfer charges accumulated in the at least one photodetector to the first floating diffusion region, and the at least one transfer transistor may be turned on in each of the third period and the sixth period.

In an image sensing device based on various embodiments of the disclosed technology, when the amount of photocharge accumulated in the at least one photodetector in the first mode is greater than the capacitance of the first floating diffusion region, the photocharge accumulated in the at least one photodetector may flow through the first DCG transistor and be accumulated in the line capacitor and the second floating diffusion region.

An imaging device based on various embodiments of the disclosed technology includes an image sensing device for generating image data by converting an optical signal into an electrical signal, and an Image Signal Processor (ISP) for performing image signal processing on the image data. The image sensing device includes a first pixel including a connection node, a second pixel arranged to be adjacent to the first pixel to share the connection node, and a line capacitor for storing a voltage of the connection node. The first pixel includes at least one photodetector, a first floating diffusion region that receives charges accumulated in the at least one photodetector, and a first dual conversion gain (DCG) transistor arranged between the first floating diffusion region and the connection node, and the second pixel includes a second floating diffusion region that receives charges accumulated in the at least one photodetector through the line capacitor, and a second DCG transistor arranged between the connection node and the second floating diffusion region.

An image sensing device and an imaging device including the same based on embodiments of the disclosed technology may provide sufficient electrostatic capacitance even when a plurality of photodetectors is saturated by including first and second pixels that share a connection node. In this way, the image sensing device and the imaging device including the same based on embodiments of the disclosed technology may enhance reliability by enhancing light detection sensitivity.

Only a few implementations and examples of the disclosed technology are described and other implementations, enhancements and variations can be made based on what is described and illustrated in this patent document

What is claimed is:

1. An image sensing device comprising:
a first pixel configured to convert received light into a first pixel electrical signal;
a second pixel configured to convert received light into a second pixel electrical signal and arranged to be adjacent to the first pixel; and
a connection node shared by the first and second pixels and configured to receive either one or both of the first and second pixel electrical signals from the first pixel or the second pixel; and
a line capacitor configured to store a voltage of the connection node,
wherein the first pixel includes: at least one first photodetector; a first floating diffusion region configured to receive photocharge from the at least one first photodetector; and a first dual conversion gain (DCG) transistor coupled between the first floating diffusion region and the connection node, and
wherein the second pixel includes: at least one second photodetector; a second floating diffusion region configured to receive photocharge from the at least one first photodetector through the line capacitor; and a second DCG transistor coupled between the connection node and the second floating diffusion region.

2. The image sensing device according to claim 1, wherein the first DCG transistor is turned off in a first mode, and the second DCG transistor is turned on in the first mode.

3. The image sensing device according to claim 2, wherein in response to an amount of photocharge accumulated in the at least one first photodetector in the first mode being greater than an amount of photocharge storable in the first floating diffusion region based on a capacitance of the first floating diffusion region, the photocharge accumulated in the at least one first photodetector flows to the line capacitor and the second floating diffusion region through the first DCG transistor upon turning on the first DCG transistor and is accumulated in the line capacitor and the second floating diffusion region.

4. The image sensing device according to claim 2, wherein the first DCG transistor is turned on in a second mode, and the second DCG transistor is turned on in the second mode.

5. The image sensing device according to claim 4, wherein, in the second mode, the photocharge is accumulated in the first floating diffusion region, the line capacitor, and the second floating diffusion region.

6. The image sensing device according to claim 4, further comprising an output line connected to the first and second pixels,
wherein the first pixel further includes: a driving transistor configured to turn on in response to a voltage of the first floating diffusion region; and a selection transistor configured to electrically connect the driving transistor to the output line, and
wherein the second pixel further includes: a driving transistor configured to turn on in response to a voltage of the second floating diffusion region; and a selection transistor configured to electrically connect the driving transistor to the output line.

7. The image sensing device according to claim 6, wherein the selection transistor of the first pixel is turned on in the first and second modes, and the selection transistor of the second pixel is turned off in the first and second modes.

8. The image sensing device according to claim 4, wherein the first pixel further includes at least one transfer transistor, each transfer transistor being in a one-to-one correspondence with a respective photodetector of the at least one photodetector to transfer photocharge accumulated in the at least one first photodetector to the first floating diffusion region, wherein the at least one transfer transistor is turned on in both the first and second modes.

9. The image sensing device according to claim 4, wherein each of the first pixel and the second pixel further includes a reset transistor configured to supply a power voltage to the connection node in response to a reset signal, wherein the reset transistor of each of the first and second pixels is turned off in both the first and second modes.

10. The image sensing device according to claim 1, wherein an electrostatic capacitance of the line capacitor is greater than an electrostatic capacitance of either the first floating diffusion region or the second floating diffusion region.

11. The image sensing device according to claim 1, wherein the at least one first photodetector includes a plurality of photodetectors, and an amount of photocharge storable in the first floating diffusion region based on a capacitance of the first floating diffusion region is lower than an amount of photocharge saturated in the plurality of photodetectors.

12. The image sensing device according to claim 1, wherein the first pixel is arranged in a first row, and the second pixel is arranged in a second row adjacent to the first row.

13. An image sensing device comprising:
a first pixel configured to detect light and arranged in a first row; and
a second pixel configured to detect light and arranged in a second row adjacent to the first row;
a connection node configured to be electrically connected to the first pixel and the second pixel,
wherein the first pixel includes: at least one first photodetector that converts light into photocharge; a first floating diffusion region configured to receive the photocharge from the at least one first photodetector; and a first dual conversion gain (DCG) transistor coupled between the first floating diffusion region and the connection node and configured to turn off in a first mode and turn on in a second mode, and
wherein the second pixel includes: at least one second photodetector that converts light into photocharge; a second floating diffusion region configured to receive the photocharge from the at least one first photodetector or the at least one second photodetector; and a second DCG transistor coupled between the connection node and the second floating diffusion region and configured to turn on in both the first mode and the second mode.

14. The image sensing device according to claim 13, wherein each of the first pixel and the second pixel further includes a reset transistor configured to supply a power voltage to the connection node in response to a reset signal, wherein the reset transistor of each of the first and second pixels is turned off during first to seventh periods that proceed sequentially.

15. The image sensing device according to claim 14, wherein the first DCG transistor is turned off during the second to fourth periods and turned on during the first, fifth to seventh periods, and the second DCG transistor is turned on during the first to seventh periods.

16. The image sensing device based on claim 14, further comprising an output line connected to the first and second pixels,
wherein the first pixel further includes: a driving transistor configured to turn on in response to a voltage of the first floating diffusion region; and a selection transistor configured to electrically connect the driving transistor to the output line, and
wherein the second pixel further includes: a driving transistor configured to turn on in response to a voltage of the second floating diffusion region; and a selection transistor configured to electrically connect the driving transistor to the output line.

17. The image sensing device according to claim 16, wherein the selection transistor of the first pixel is turned on during the first to seventh periods, and the selection transistor of the second pixel is turned off during the first to seventh periods.

18. The image sensing device according to claim 14, wherein the first pixel further includes at least one transfer transistor, each transfer transistor being in a one-to-one correspondence with a respective photodetector of the at least one photodetector to transfer photocharge accumulated in the at least one photodetector to the first floating diffusion region, wherein the at least one first transfer transistor is turned on in both the third period and the sixth period.

19. The image sensing device according to claim 13, wherein in response to an amount of photocharge accumulated in the at least one first photodetector in the first mode being greater than an amount of photocharge storable in the first floating diffusion region based on a capacitance of the first floating diffusion region, the photocharge accumulated in the at least one first photodetector flows to a line capacitor and the second floating diffusion region through the first DCG transistor upon turning on the first DCG transistor and is accumulated in the line capacitor and the second floating diffusion region.

20. An imaging device comprising:
an image sensing device configured to generate image data by sensing incident light; and
an image signal processor configured to perform image signal processing on the image data,
wherein the image sensing device includes: a first pixel for sensing the incident light; a second pixel for sensing the incident light and arranged adjacent to the first pixel, and a connection node, wherein the first and second pixels share the connection node; and a line capacitor coupled to the connection node and configured to store a voltage of the connection node,
wherein the first pixel includes: at least one first photodetector that converts received light into photocharge; a first floating diffusion region configured to receive the photocharge from the at least one first photodetector; and a first dual conversion gain (DCG) transistor coupled between the first floating diffusion region and the connection node, and
the second pixel includes: at least one second photodetector that converts received light into photocharge; a second floating diffusion region configured to receive the photocharge from the at least one first photodetector of the first pixel through the line capacitor; and a second DCG transistor coupled between the connection node and the second floating diffusion region.
